(19) United States
(12) Patent Application Publication
(10) Pub. No.: US 2026/0215282 A1
(43) Pub. Date: Jul. 23, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: KeJing Yu, Kaohsiung City (TW); Ru-Shang Hsiao, Jhubei City (TW)

(73) Assignee: Taiwan Semiconductor Manufacturing Company, Ltd., Hsinchu (TW)

(21) Appl. No.: 19/032,786

(22) Filed: Jan. 21, 2025

(51) Int. Cl. H01L 23/552; H01L 23/58; H10B 12/00; H10B 61/00; H10B 63/00

(52) U.S. Cl. CPC H10W 42/20; H10B 12/31; H10B 61/10; H10B 63/30; H10W 42/00

(57) ABSTRACT

A semiconductor structure includes: an interconnect structure including a plurality of interconnect layers formed over a substrate and a storage structure in the interconnect structure. The storage structure includes a first electrode, a second electrode, and a first storage layer disposed between the first electrode and the second electrode. The storage structure includes a first portion in a first interconnect layer and a second portion in a second interconnect layer. The semiconductor structure further includes a shield structure disposed in the first interconnect layer and the second interconnect layer of the interconnect structure, wherein the shield structure surrounds the storage structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of an example semiconductor structure, according to some embodiments.

FIG. 1B illustrates a cross-sectional view of another example semiconductor structure, according to some embodiments.

FIG. 2A is a diagram depicting a top view of a semiconductor structure comprising an example storage element with an example shield ring surrounding the storage element, according to some embodiments.

FIG. 2B is a diagram depicting a cross-sectional view of the example storage element along cut line 1, according to some embodiments.

FIG. 2C is a diagram depicting a top view of another semiconductor structure comprising an example storage element with an example shield ring surrounding the storage element, according to some embodiments.

FIG. 2D is a diagram depicting a cross-sectional view of the example storage element along cut line 2, according to some embodiments.

FIG. 3A illustrates a cross-sectional view of another example semiconductor structure, according to some embodiments.

FIG. 3B illustrates a cross-sectional view of another example semiconductor structure, according to some embodiments.

FIG. 4 is a diagram providing a three-dimensional view of a portion of an example semiconductor structure, according to some embodiments.

FIGS. 5A-5H are diagrams depicting top perspective views of example semiconductor structures comprising a storage element with an example shield ring surrounding the storage element, according to some embodiments.

FIGS. 6A-6H are diagrams depicting top perspective views of example semiconductor structures comprising a storage element with an example shield ring surrounding the storage element, according to some embodiments.

FIG. 7A-7E are diagrams depicting top perspective views of example semiconductor structures comprising a storage element with an example shield ring surrounding the storage element, according to some embodiments.

FIG. 8 is a process flow chart depicting an example fabrication method according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions, and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

Various embodiments are discussed herein in a particular context, namely, for forming a semiconductor structure that includes a fin-like field-effect transistor (FinFET) device. The semiconductor structure, for example, may be a complementary metal-oxide-semiconductor (CMOS) device including a P-type metal-oxide-semiconductor (PMOS) FinFET device and an N-type metal-oxide-semiconductor (NMOS) FinFET device. Embodiments will now be described with respect to particular examples including FinFET manufacturing processes. Embodiments, however, are not limited to the examples provided herein, and the ideas may be implemented in a wide array of embodiments. Thus, various embodiments may be applied to other semiconductor devices/processes, such as planar transistors, and the like. Further, embodiments discussed herein are discussed in the context of devices formed using a gate-last process.

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

The present disclosure is generally related to semiconductor devices and the fabrication thereof, and in some cases to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. These multi-gate devices may also include a CFET wherein a first gate-all-around field effect transistor (GAA FET) is disposed over a substrate and a second GAA FET is disposed above the first GAA FET. The first GAA FET includes a first source and a first drain, and the second GAA FET includes a second source and the second drain. The source/drain of the first GAA FET is electrically separated from the source/drain of the second GAA FET in some embodiments. A gate structure including a gate dielectric layer and a gate electrode layer is commonly formed around the channel region of the first and second GAA FETs. In some embodiments, the first GAA FET is a first conductivity type (e.g., n-type) FET and the second GAA FET is a second conductivity type (e.g., p-type) different from the first conductivity type. In other embodiments, the first and second GAA FETs have the same conductivity type. Presented herein are embodiments of devices that may have one or more channel regions (e.g., nanosheets) associated with a single, contiguous gate structure. However, one of ordinary skill would recognize that the teaching can apply to a single channel or any number of channels, such as a FinFET device, on account of its fin-like structure. One of ordinary skill may recognize other examples of semiconductor devices that may benefit from aspects of the present disclosure.

Described herein are systems, methods, techniques, and articles for shielding storage elements such as capacitors, RAM cells, and RAM arrays from interference or noise from RF energy from other components in a semiconductor structure.

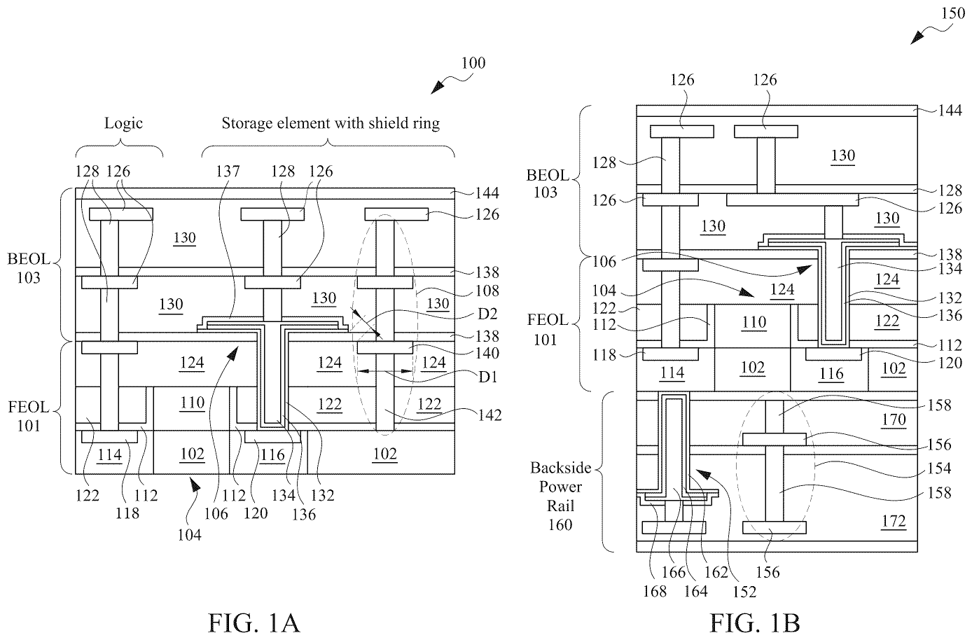

FIG. 1A illustrates a cross-sectional view of an example semiconductor structure 100, according to some embodiments. Note that for clarity, not all features of the semiconductor structure 100 are illustrated in FIG. 1A and FIG. 1A may illustrate only a portion of the semiconductor structure formed. The example semiconductor structure 100 includes structures formed during a front-end-of-line (FEOL) manufacturing process in a FEOL layer 101 and structures formed during a back-end-of-line (BEOL) manufacturing process in a BEOL layer 103. The example semiconductor structure 100 includes a substrate 102, a transistor device 104 formed on the substrate 102, a storage element 106 formed on the substrate 102, and a shield ring 108 formed around the storage element 106. A passivation layer 144 may be formed over the semiconductor structure 100.

The substrate 102 may be a semiconductor substrate, such as silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Devices, such as transistors, diodes, capacitors, resistors, etc., may be formed in and/or on the substrate and may be interconnected by interconnect structures formed by, for example, metallization patterns in one or more dielectric layers over the substrate.

The transistor device 104 includes a gate structure 110 formed over a channel region of the substrate 102, gate spacers 112 surrounding the gate structure 110, a first epitaxial grown source/drain region 114 and a second epitaxial grown source/drain region 116. The transistor device 104 further includes a first silicide region 118 on the first source/drain region 114 and a second silicide region 120 on the second source/drain region 116. A first interlayer dielectric layer (ILD0 layer 122) is formed over and around the gate spacers 112 and a second interlayer dielectric layer (ILD1 layer 124) is formed over the ILD0 layer 122.

The example transistor device 104 may be a metal-oxide-semiconductor field effect transistor (MOSFET) device. In various embodiments, the transistor device 104 may be an n-FET device. In other embodiments, the transistor device 104 may be a p-FET device. In this example, the transistor device 104 is formed by FEOL processes and may be considered as an FEOL structure in the FEOL layer 101.

Although the disclosed embodiments are described with reference to a planar MOSFET device, in other embodiments, the transistor device 104 may be a FinFET device, a gate-all-around (GAA) device, CFET device, and other suitable type of transistor device.

In some embodiments, the semiconductor structure 100 further includes, but is not limited thereto, other types of transistors, capacitors, resistors, or the like. The transistor device 104 is electrically connected to the storage element 106 via an interconnection structure disposed over the substrate 102 and the ILD1 layer 124. In certain embodiments, the interconnection structure is formed by BEOL processes and may be considered as a BEOL structure in the BEOL layer 103.

In some embodiments, the interconnection structure comprises a plurality of stacked interconnect metal layers that include interconnect metal lines 126 and VIAs 128 embedded in an insulating material layer 130 for interconnecting the transistor device 104 and the storage element 106, and for electrically connecting the transistor device 104 with other above layers. Although only one transistor device 104 is shown in FIG. 1A, it is well understood that multiple tiers or layers of transistors may be formed. Although only two stacked interconnect metal layers are shown, in various embodiments, more than two stacked interconnect metal layers may be provided.

Conductive material for the interconnect metal lines 126 and/or VIAs 128 may be formed from conductive material, such as copper (Cu), aluminum (Al), tungsten (W), nickel, cobalt, silver, combinations thereof, or other applicable materials, and may be formed using an electro-chemical plating process, chemical vapor deposition (CVD), atomic layer deposition (ALD), physical vapor deposition (PVD), the like, or a combination thereof. After formation of the conductive material, excess conductive material may be removed using, for example, a planarization process such as chemical mechanical polishing (CMP). The interconnect structure may include one or more metal layers and one or more intermetal dielectric (IMD) layers.

The storage element 106 is formed by BEOL processes and may be considered as a BEOL structure in the BEOL layer 103. The storage element 106 is disposed within the interconnect structure.

The example storage element 106 comprises a bottom electrode or capacitor bottom metal layer (CBM layer 132), a top electrode or capacitor top metal layer (CTM layer 134), and a storage layer 136 sandwiched between the CBM layer 132 and the CTM layer 134. In various embodiments, the storage element 106 is formed as a T-shape structure with a first portion of the CBM layer 132, storage layer 136, and the CTM layer 134 formed in the interconnect structure above an etch stop layer 138 and extending in a horizontal direction, and a second portion of the CBM layer 132, storage layer 136, and the CTM layer 134 extending in a vertical direction in a trench in the ILD1 and ILD2 and landing on the second silicide region 120. The second portion of the CBM layer 132, storage layer 136, and the CTM layer 134 can be formed in a trench to improve the memory or capacitance capability of the storage element 106. In this example, the first portion of CBM layer 132, storage layer 136, and the CTM layer 134 is oriented at an angle of approximately 90 degrees from the second portion of the CBM layer 132, storage layer 136, and the CTM layer 134 in the trench. In other embodiments, the storage element may not have a portion formed in a trench, or may not be formed as a T-shaped structure with a second portion that is oriented at an angle of approximately 90 degrees from a first portion and extending in a vertical direction. In various embodiments, a cap layer 137 comprising, for example, SiN, may be formed over the storage element 106 between the storage element 106 and the insulating material layer 130.

In some embodiments, the CBM layer 132 and the CTM layer 134 may comprise titanium (Ti), tantalum (Ta), Hafnium (Hf), tantalum nitride (TaN), titanium nitride (TiN), ruthenium (Ru), Platinum (Pt), Gold (Au), Silver (Ag), Copper (Cu), Zirconium (Zr), Aluminum (Al), Lead (Pb), Tungsten (W), Iridium (Ir), Cobalt (Co), Zinc (Zn), Molybdenum (Mo), Gallium (Ga), Germanium (Ge), Palladium (Pd), Indium tin oxide (ITO), Indium zinc oxide (IZO) or other suitable material. The CBM layer 132 and the CTM layer 134 may be formed from a single film, composite film, or dopant film.

In some embodiments, the storage layer 136 includes a dielectric material, such as Hafnium (HfO), Zirconium oxide (ZrO), hafnium zirconium oxide (HfZrO), aluminum oxide (AlO), and/or Silicon nitride (SiN). In such embodiments, the storage element 106 may function as a capacitor or a random access memory (RAM) cell.

In some embodiments, the storage layer 136 comprises a material having a variable resistance configured to undergo a reversible phase change between a high resistance state and a low resistance. In various embodiments, a high-k dielectric material such as Al₂O₃, ZrSiO₄, Si₃N₄, MgO, CaO, Y₂O₃, SrO, Ta₂O₅, ZrO₂, HfO₂, La₂O₃, BaO, LaLuO₂, and/or TiO₂, or other suitable compounds may be used.

In such cases, the storage element 106 may function as a resistive memory cell, and may be combined with an array of such storage elements to form a resistive random access memory (ReRAM or RRAM) device. Depending on voltages applied to the electrodes, the storage layer 136 will undergo a reversible change between a high resistance state associated with a first data state (e.g., a ‘0’ or ‘RESET’) and a low resistance state associated with a second data state (e.g., a ‘1’ or ‘SET’). Once a resistance state is set, an RRAM cell will retain the resistive state until another voltage is applied to induce a RESET operation (resulting in a high resistance state) or a SET operation (resulting in a low resistance state).

In some embodiments, the storage layer 136 comprises magnetic tunnel junction (MTJ) material or spin-valve material. In such cases, the storage element 106 may function as a magnetoresistive memory cell and may be combined with an array of such storage elements to form a magnetoresistive random access memory (MRAM) device.

In some further embodiments, the storage layer 136 comprises a phase-change material, such as Ge₂Sb₂Te₅, and may be combined with an array of such storage elements to form a PCRAM device. Other suitable types of structures for the storage layer 136 and storage element 106 may be contemplated.

In some further embodiments, the storage layer 136 comprises a ferroelectric tunnel junction (FTJ) material that includes Fe material (such as a ferroelectric oxide) and interfacial layer (IL) material. The Fe material may be formed of a suitable ferroelectric material, such as perovskite, rutile, or orthorhombic thin film. The IL may be formed of a suitable non-polar material, such as SiO₂, Al₂O₃, Ta₂O₅, TiO₂, TaON, etc. The storage layer 136 may be combined with an array of such storage elements to form a ferroelectric random-access memory (FeRAM) device. The FeRAM stores information using the spontaneous polarization of Fe material in the storage layer 136.

The shield ring 108 is formed around a substantial portion of the storage element 106. The shield ring 108 is provided to protect the storage element 106 from electrical noise from current/electric fields associated with various interconnect metal lines 126 and/or VIAs 128 in the interconnection structure. The shield ring 108 comprises a plurality of metal lines 140 and vertically extending wall units 142 that collectively form a wall that is formed in the same architectural layer as the storage element 106. In some cases, the shield ring 108 may extend to additional architectural layers above or below the storage element 106.

In this example, the storage element 106 is formed in two architectural layers—a first architectural layer above the substrate 102 and a first architectural layer in the interconnect structure. The shield ring 108 is also formed in the first architectural layer above the substrate 102 and a first architectural layer in the interconnect structure plus the second architectural layer in the interconnect structure. This allows the shield ring 108 to protect the storage element 106 from noise.

In various embodiments, the shield ring 108 has a width (D1 measured across metal lines 140) greater than (>) 30 nm. In various embodiments, the shield ring 108 can be arranged to protect a single storage element 106 or multiple storage element 106. In various embodiments, a distance (D2) between the shield ring 108 and the CBM layer 132 of the storage element 106 is greater than 20 nm. The geometric design of the shield ring 108 can be adapted to fit different configurations of storage element(s) 106 protected by the shield ring 108.

The shield ring 108 may be formed from Tungsten (W), Cobalt (Co), ruthenium (Ru), Aluminum (Al), Copper (Cu), or other suitable material. The shield ring 108 may be formed from a single film, composite film, or dopant film.

FIG. 1B illustrates a cross-sectional view of another example semiconductor structure 150, according to some embodiments. Note that for clarity, not all features of the semiconductor structure 150 are illustrated in FIG. 1B and FIG. 1B may illustrate only a portion of the semiconductor structure formed. The example semiconductor structure 150 includes structures formed during a FEOL manufacturing process and structures formed during a BEOL manufacturing process. The example semiconductor structure 150 includes components similar to components of semiconductor structure 100, such as a substrate 102, a transistor device 104 formed on the substrate 102, and a first storage element 106 formed on the substrate 102. The example semiconductor structure 150 further includes a second storage element 152 formed below the substrate 102 in a backside power rail region 160 of the semiconductor structure 150 and a shield ring 154 formed around the second storage element 152. In some embodiments, the semiconductor structure 150 further includes, but is not limited thereto, other types of transistors, capacitors, resistors, or the like. A passivation layer 144 may be formed over the semiconductor structure 150.

The transistor device 104 is electrically connected to the first storage element 106 via an interconnection structure disposed over the substrate 102 and the ILD1 layer 124, and electrically connected to the second storage element 152 via the interconnection structure in the backside power rail region 160. In some embodiments, the interconnection structure comprises a plurality of stacked interconnect metal layers that include interconnect metal lines 126 and VIAs 128 embedded in an insulating material layer 130 for interconnecting the transistor device 104 and the first storage element 106, for interconnecting the transistor device 104 and the second storage element 152, and for electrically connecting the transistor device 104 with other layers. Although only one transistor device 104 is shown in FIG. 1B, it is well understood that multiple tiers or layers of transistors may be formed. Although only a few stacked interconnect metal layers are shown, in various embodiments, additional stacked interconnect metal layers may be provided.

The second storage element 152 may be formed by BEOL processes and may be considered as a BEOL structure. The second storage element 152 is disposed within the interconnect structure. The example second storage element 152 comprises a bottom electrode or capacitor bottom metal layer (CBM layer 162), a top electrode or capacitor top metal layer (CTM layer 164), and a storage layer 166 sandwiched between the CBM layer 162 and the CTM layer 164. In various embodiments, the second storage element 152 is formed as a T-shape structure with a first portion of the CBM layer 162, storage layer 166, and the CTM layer 164 formed in the interconnect structure above an etch stop layer 138 and extending in a horizontal direction, and a second portion of the CBM layer 162, storage layer 166, and the CTM layer 164 extending in a vertical direction in a trench in a first inter metal dielectric (IMD) layer 170 and a second IMD layer 172 in the backside power rail region 160 and landing on the first source/drain region 114. The second portion of the CBM layer 162, storage layer 166, and the CTM layer 164 can be formed in a trench to improve the memory or capacitance capability of the second storage element 152. In this example, the first portion of the second storage element 152 is oriented at an angle of approximately 90 degrees from the second portion of the second storage element in the trench. In other embodiments, the storage element may not have a portion formed in a trench, or may not be formed as a T-shaped structure with a second portion that is oriented at an angle of approximately 90 degrees from a first portion. In various embodiments, a cap layer 168 comprising, for example, SiN, may be formed over the second storage element 152 between the second storage element 152 and the second IMD layer 172.

In some embodiments, the CBM layer 162 and the CTM layer 164 may comprise titanium (Ti), tantalum (Ta), Hafnium (Hf), tantalum nitride (TaN), titanium nitride (TiN), ruthenium (Ru), Platinum (Pt), Gold (Au), Silver (Ag), Copper (Cu), Zirconium (Zr), Aluminum (Al), Lead (Pb), Tungsten (W), Iridium (Ir), Cobalt (Co), Zinc (Zn), Molybdenum (Mo), Gallium (Ga), Germanium (Ge), Palladium (Pd), Indium tin oxide (ITO), Indium zinc oxide (IZO) or other suitable material. The CBM layer 162 and the CTM layer 164 may be formed from a single film, composite film, or dopant film.

In some embodiments, the storage layer 166 includes a dielectric material, such as Hafnium (HfO), Zirconium oxide (ZrO), hafnium zirconium oxide (HfZrO), aluminum oxide (AlO), and/or Silicon nitride (SiN). In such embodiments, the second storage element 152 may function as a capacitor or a random access memory (RAM) cell.

In some embodiments, the storage layer 166 comprises a material having a variable resistance configured to undergo a reversible phase change between a high resistance state and a low resistance. In various embodiments, a high-k dielectric material such as such as Al₂O₃, ZrSiO₄, Si₃N₄, MgO, CaO, Y₂O₃, SrO, Ta₂O₅, ZrO₂, HfO₂, La₂O₃, BaO, LaLuO₂, and/or TiO₂, or other suitable compounds may be used.

In such cases, the second storage element 152 may function as a resistive memory cell, and may be combined with an array of such storage elements to form a resistive random access memory (ReRAM or RRAM) device. Depending on voltages applied to the electrodes, the storage layer 166 will undergo a reversible change between a high resistance state associated with a first data state (e.g., a ‘0’ or ‘RESET’) and a low resistance state associated with a second data state (e.g., a ‘1’ or ‘SET’). Once a resistance state is set, an RRAM cell will retain the resistive state until another voltage is applied to induce a RESET operation (resulting in a high resistance state) or a SET operation (resulting in a low resistance state).

In some embodiments, the storage layer 166 comprises magnetic tunnel junction (MTJ) material or spin-valve material. In such cases, the second storage element 152 may function as a magnetoresistive memory cell and may be combined with an array of such storage elements to form a magnetoresistive random access memory (MRAM) device.

In some further embodiments, the storage layer 166 comprises a phase-change material, such as Ge₂Sb₂Te₅, and may be combined with an array of such storage elements to form a PCRAM device. Other suitable types of structures for the storage layer 166 and the second storage element 152 may be contemplated.

In some further embodiments, the storage layer 166 comprises a ferroelectric tunnel junction (FTJ) material that includes Fe material (such as a ferroelectric oxide) and interfacial layer (IL) material. The Fe material may be formed of a suitable ferroelectric material, such as perovskite, rutile, or orthorhombic thin film. The IL may be formed of a suitable non-polar material, such as SiO₂, Al₂O₃, Ta₂O₅, TiO₂, TaON, etc. The storage layer 166 may be combined with an array of such storage elements to form a ferroelectric random-access memory (FeRAM) device. The FeRAM stores information using the spontaneous polarization of Fe material in the storage layer 166.

The shield ring 154 is formed around a substantial portion of the second storage element 152. The shield ring 154 is provided to protect the second storage element 152 from electrical noise from current/electric fields associated with various interconnect metal lines and/or VIAs in the backside power rail region 160. The shield ring 154 comprises a plurality of metal lines 156 and wall units 158 (which collectively form a wall) that is formed in the same architectural layer as the second storage element 152. Because the second storage element 152 is coupled to the first source/drain region 114 and disposed in the first IMD layer 170 and the second IMD layer 172, the shield ring 154 is formed below the gate structure 110 and disposed in the first IMD layer 170 and the second IMD layer 172. In some cases, the shield ring 154 may extend to additional architectural layers above or below the second storage element 152.

In this example, the second storage element 152 is formed in the two architectural layers of the backside power rail region 160. The shield ring 154 is also formed in the two architectural layers of the backside power rail region 160. This allows the shield ring 154 to protect the second storage element 152 from noise.

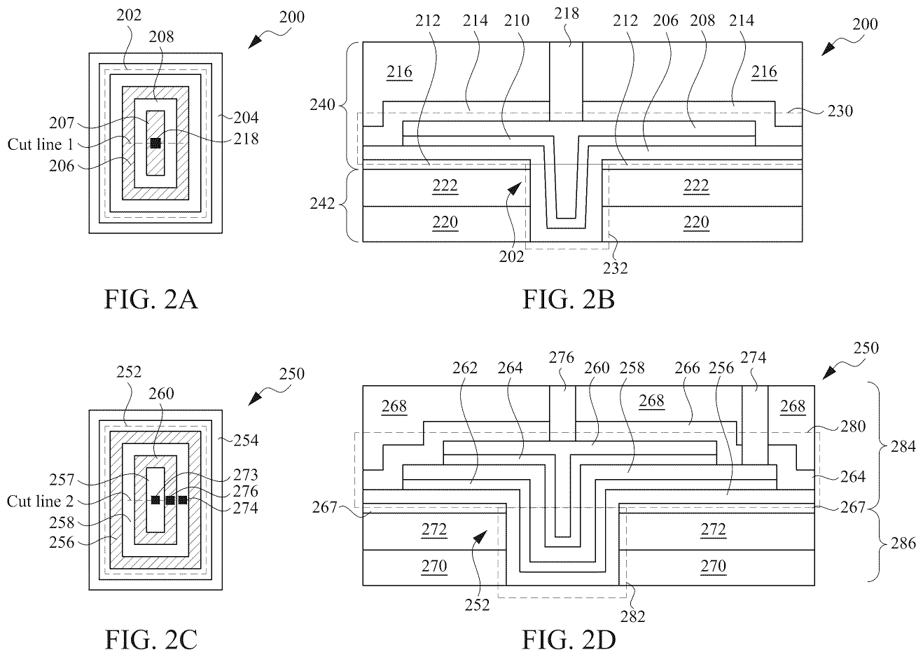

FIG. 2A is a diagram depicting a top view of a semiconductor structure 200 comprising an example storage element 202 with an example shield ring 204 surrounding the storage element 202, according to some embodiments. FIG. 2B is a diagram depicting a cross-sectional view of the example storage element 202 along cut line 1, according to some embodiments. The example storage element 202 comprises a bottom electrode or capacitor bottom metal layer (CBM layer 206), a top electrode or capacitor top metal layer (CTM layer 208), and a storage layer 210 sandwiched between the CBM layer 206 and the CTM layer 208. In various embodiments, the storage element 202 is formed as a T-shape structure with a first portion 230 of the storage element 202 (comprising a first portion of the CBM layer 206, storage layer 210, and the CTM layer 208) formed in a first interconnect layer 240 of the interconnect structure above an etch stop layer 212 and extending in a horizontal direction, and a second portion 232 of the storage element 202 (comprising a second portion of the CBM layer 206, storage layer 210, and the CTM layer 208) formed in a trench 207 in a second interconnect layer 242 that includes a first inter metal dielectric layer (IMD layer 220) and a second IMD layer 222 and extending in a vertical direction. The second portion of the CBM layer 206, storage layer 210, and the CTM layer 208 can be formed in the trench 207 to improve the memory or capacitance capability of the storage element 202. In this example, the first portion of the CBM layer 206, storage layer 210, and the CTM layer 208 is oriented at an angle of approximately 90 degrees from the second portion of the CBM layer 206, storage layer 210, and the CTM layer 208 in the trench 207. In various embodiments, a cap layer 214 comprising, for example, SiN, may be formed over the storage element 202 between the storage element 202 and the insulating material layer 216. The CBM layer 206 may connect to an underlying contact or metal line and the CTM layer 208 may be accessed by a VIA 218.

In some embodiments, the CBM layer 206 and the CTM layer 208 may comprise titanium (Ti), tantalum (Ta), Hafnium (Hf), tantalum nitride (TaN), titanium nitride (TiN), ruthenium (Ru), Platinum (Pt), Gold (Au), Silver (Ag), Copper (Cu), Zirconium (Zr), Aluminum (Al), Lead (Pb), Tungsten (W), Iridium (Ir), Cobalt (Co), Zinc (Zn), Molybdenum (Mo), Gallium (Ga), Germanium (Ge), Palladium (Pd), Indium tin oxide (ITO), Indium zinc oxide (IZO) or other suitable material. The CBM layer 206 and the CTM layer 208 may be formed from a single film, composite film, or dopant film.

In some embodiments, the storage layer 210 includes a dielectric material, such as Hafnium (HfO), Zirconium oxide (ZrO), hafnium zirconium oxide (HfZrO), aluminum oxide (AlO), and/or Silicon nitride (SiN). In such embodiments, the storage element 202 may function as a capacitor or a random access memory (RAM) cell.

In some embodiments, the storage layer 210 comprises a material having a variable resistance configured to undergo a reversible phase change between a high resistance state and a low resistance. In various embodiments, a high-k dielectric material such as such as Al₂O₃, ZrSiO₄, Si₃N₄, MgO, CaO, Y₂O₃, SrO, Ta₂O₅, ZrO₂, HfO₂, La₂O₃, BaO, LaLuO₂, and/or TiO₂, or other suitable compounds may be used.

In such cases, the storage element 202 may function as a resistive memory cell, and may be combined with an array of such storage elements to form a resistive random access memory (ReRAM or RRAM) device. Depending on voltages applied to the electrodes, the storage layer 210 will undergo a reversible change between a high resistance state associated with a first data state (e.g., a ‘0’ or ‘RESET’) and a low resistance state associated with a second data state (e.g., a ‘1’ or ‘SET’). Once a resistance state is set, an RRAM cell will retain the resistive state until another voltage is applied to induce a RESET operation (resulting in a high resistance state) or a SET operation (resulting in a low resistance state).

In some embodiments, the storage layer 210 comprises magnetic tunnel junction (MTJ) material or spin-valve material. In such cases, the storage element 202 may function as a magnetoresistive memory cell and may be combined with an array of such storage elements to form a magnetoresistive random access memory (MRAM) device.

In some further embodiments, the storage layer 210 comprises a phase-change material, such as Ge₂Sb₂Te₅, and may be combined with an array of such storage elements to form a PCRAM device. Other suitable types of structures for the storage layer 210 and the storage element 202 may be contemplated.

In some further embodiments, the storage layer 210 comprises a ferroelectric tunnel junction (FTJ) material that includes Fe material (such as a ferroelectric oxide) and interfacial layer (IL) material. The Fe material may be formed of a suitable ferroelectric material, such as perovskite, rutile, or orthorhombic thin film. The IL may be formed of a suitable non-polar material, such as SiO₂, Al₂O₃, Ta₂O₅, TiO₂, TaON, etc. The storage layer 210 may be combined with an array of such storage elements to form a ferroelectric random-access memory (FeRAM) device. The FeRAM stores information using the spontaneous polarization of Fe material in the storage layer 210.

FIG. 2C is a diagram depicting a top view of another semiconductor structure 250 comprising an example storage element 252 with an example shield ring 254 surrounding the storage element 252, according to some embodiments. FIG. 2D is a diagram depicting a cross-sectional view of the example storage element 252 along cut line 2, according to some embodiments. The example storage element 252 comprises a first electrode 256, a second electrode 258, a third electrode 260, a first storage layer 262 sandwiched between the first electrode 256 and the second electrode 258, and a second storage layer 264 sandwiched between the second electrode 258 and the third electrode 260. In various embodiments, the storage element 252 is formed as a T-shape structure with a first portion 280 of the storage element 252 (comprising a first portion of the first electrode 256, second electrode 258, third electrode 260, first storage layer 262, and second storage layer 264) formed in a first interconnect layer 284 of an interconnect structure above an etch stop layer 267 and extending in a horizontal direction, and a second portion 282 of the storage element 252 (comprising a second portion of the first electrode 256, second electrode 258, third electrode 260, first storage layer 262, and second storage layer 264) formed in a trench 257 in a second interconnect layer 286 that includes first IMD layer 270 and a second IMD layer 272 and extending in a vertical direction. The second portion of the storage element 252 can be formed in the trench 257 to improve the memory or capacitance capability of the storage element 252. In this example, the first portion of the storage element 252 is oriented at an angle of approximately 90 degrees from the second portion of the storage element 252 in the trench 257. In various embodiments, a cap layer 266 comprising, for example, SiN, may be formed over the storage element 252 between the storage element 252 and the insulating material layer 268. The first electrode 256 may connect to an underlying contact or metal line by a VIA 273, the second electrode 258 may be accessed by a VIA 274, and the third electrode 260 may be accessed by a VIA 276.

In some embodiments, the first electrode 256, the second electrode 258, and the third electrode 260 may comprise titanium (Ti), tantalum (Ta), Hafnium (Hf), tantalum nitride (TaN), titanium nitride (TiN), ruthenium (Ru), Platinum (Pt), Gold (Au), Silver (Ag), Copper (Cu), Zirconium (Zr), Aluminum (Al), Lead (Pb), Tungsten (W), Iridium (Ir), Cobalt (Co), Zinc (Zn), Molybdenum (Mo), Gallium (Ga), Germanium (Ge), Palladium (Pd), Indium tin oxide (ITO), Indium zinc oxide (IZO) or other suitable material. The first electrode 256, the second electrode 258, and the third electrode 260 may be formed from a single film, composite film, or dopant film.

In some embodiments, the first storage layer 262 and the second storage layer 264 include a dielectric material, such as Hafnium (HfO), Zirconium oxide (ZrO), hafnium zirconium oxide (HfZrO), aluminum oxide (AlO), and/or Silicon nitride (SiN). In such embodiments, the storage element 252 may function as a capacitor or a random access memory (RAM) cell.

In some embodiments, the first storage layer 262 and the second storage layer 264 comprises a material having a variable resistance configured to undergo a reversible phase change between a high resistance state and a low resistance. In various embodiments, a high-k dielectric material such as such as Al₂O₃, ZrSiO₄, Si₃N₄, MgO, CaO, Y₂O₃, SrO, Ta₂O₅, ZrO₂, HfO₂, La₂O₃, BaO, LaLuO₂, and/or TiO₂, or other suitable compounds may be used.

In such cases, the storage element 252 may function as a resistive memory cell, and may be combined with an array of such storage elements to form a resistive random access memory (ReRAM or RRAM) device. Depending on voltages applied to the electrodes, the first storage layer 262 and the second storage layer 264 will undergo a reversible change between a high resistance state associated with a first data state (e.g., a ‘0’ or ‘RESET’) and a low resistance state associated with a second data state (e.g., a ‘1’ or ‘SET’). Once a resistance state is set, an RRAM cell will retain the resistive state until another voltage is applied to induce a RESET operation (resulting in a high resistance state) or a SET operation (resulting in a low resistance state).

In some embodiments, the first storage layer 262 and the second storage layer 264 comprise magnetic tunnel junction (MTJ) material or spin-valve material. In such cases, the storage element 252 may function as a magnetoresistive memory cell and may be combined with an array of such storage elements to form a magnetoresistive random access memory (MRAM) device.

In some further embodiments, the first storage layer 262 and the second storage layer 264 comprise a phase-change material, such as Ge₂Sb₂Te₅, and may be combined with an array of such storage elements to form a PCRAM device. Other suitable types of structures for the first storage layer 262, the second storage layer 264, and the storage element 252 may be contemplated.

In some further embodiments, the first storage layer 262 and the second storage layer 264 comprise a ferroelectric tunnel junction (FTJ) material that includes Fe material (such as a ferroelectric oxide) and interfacial layer (IL) material. The Fe material may be formed of a suitable ferroelectric material, such as perovskite, rutile, or orthorhombic thin film. The IL may be formed of a suitable non-polar material, such as SiO₂, Al₂O₃, Ta₂O₅, TiO₂, TaON, etc. the first storage layer 262 and the second storage layer 264 may be combined with an array of such storage elements to form a ferroelectric random-access memory (FeRAM) device. The FeRAM stores information using the spontaneous polarization of Fe material in the first storage layer 262 and the second storage layer 264.

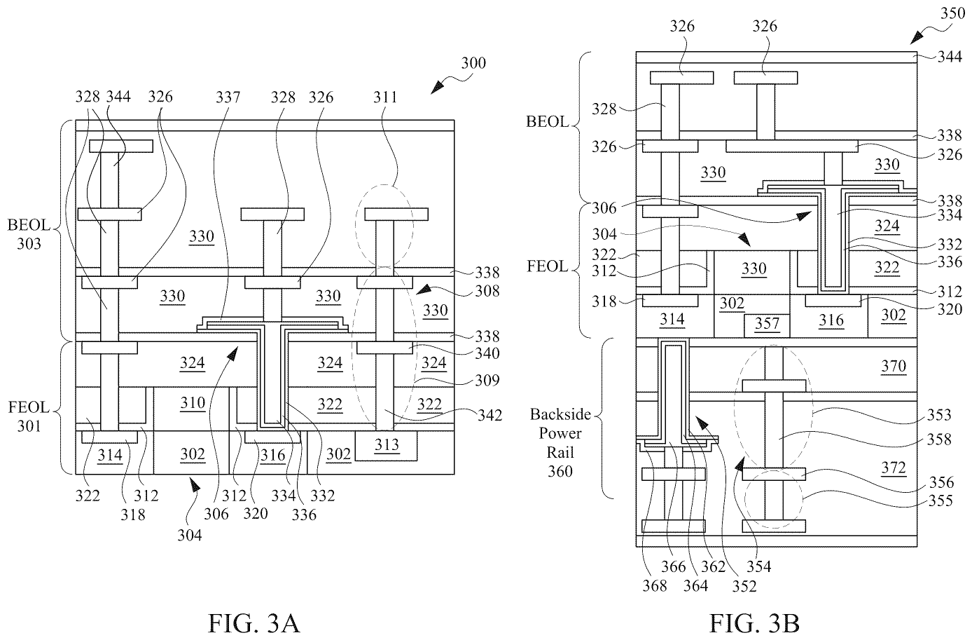

FIG. 3A illustrates a cross-sectional view of another example semiconductor structure 300, according to some embodiments. Note that for clarity, not all features of the semiconductor structure 300 are illustrated in FIG. 3A and FIG. 3A may illustrate only a portion of the semiconductor structure formed. The example semiconductor structure 300 includes structures formed during a front-end-of-line (FEOL) manufacturing process in a FEOL layer 301 and structures formed during a back-end-of-line (BEOL) manufacturing process in a BEOL layer 303. The example semiconductor structure 300 includes a substrate 302 (e.g., similar to substrate 102), a transistor device 304 (e.g., similar to transistor device 104) formed on the substrate 302, a storage element 306 (e.g., similar to storage element 106) formed on the substrate 302, and a shield ring 308 (e.g., similar to shield ring 108) formed around the storage element 306. A passivation layer 344 may be formed over the semiconductor structure 300.

The transistor device 304 includes a gate structure 310 formed over a channel region of the substrate 302, gate spacers 312 surrounding the gate structure 310, a first epitaxial grown source/drain region 314 and a second epitaxial grown source/drain region 316. The transistor device 304 further includes a first silicide region 318 on the first source/drain region 314 and a second silicide region 320 on the second source/drain region 316. A first interlayer dielectric layer (ILD0 layer 322) is formed over and around the gate spacers 312 and a second interlayer dielectric layer (ILD1 layer 324) is formed over the ILD0 layer 322. In this example, the transistor device 304 is formed by FEOL processes and may be considered as an FEOL structure in the FEOL layer 301. Although the disclosed embodiments are described with reference to a planar MOSFET device, in other embodiments, the transistor device 304 may be a FinFET device, a GAA device, CFET device, and other suitable type of transistor device.

In some embodiments, the semiconductor structure 300 further includes, but is not limited thereto, other types of transistors, capacitors, resistors, or the like. The transistor device 304 is electrically connected to the storage element 306 via an interconnection structure disposed over the substrate 302 and the ILD1 layer 324. In certain embodiments, the interconnection structure is formed by BEOL processes and may be considered as a BEOL structure in the BEOL layer 303.

In some embodiments, the interconnection structure comprises a plurality of stacked interconnect metal layers that include interconnect metal lines 326 and VIAs 328 embedded in an insulating material layer 330 for interconnecting the transistor device 304 and the storage element 306, and for electrically connecting the transistor device 304 with other above layers. Although only one transistor device 304 is shown in FIG. 3A, it is well understood that multiple tiers or layers of transistors may be formed. Although only two stacked interconnect metal layers are shown, in various embodiments, more than two stacked interconnect metal layers may be provided.

The storage element 306 is formed by BEOL processes and may be considered as a BEOL structure in the BEOL layer 303. The storage element 306 is disposed within the interconnect structure.

The example storage element 306 comprises a bottom electrode or capacitor bottom metal layer (CBM layer 332), a top electrode or capacitor top metal layer (CTM layer 334), and a storage layer 336 (e.g., similar to storage layer 136) sandwiched between the CBM layer 332 and the CTM layer 334. In various embodiments, the storage element 306 is formed as a T-shape structure with a first portion of the storage element 306 formed in the interconnect structure above an etch stop layer 338 and extending in a horizontal direction, and a second portion of the storage element 306 formed in a trench in the ILD1 and ILD2 and landing on the second silicide region 320 and extending in a vertical direction. The second portion of the storage element 306 can be formed in a trench to improve the memory or capacitance capability of the storage element 306. In various embodiments, a cap layer 337 comprising, for example, SiN, may be formed over the storage element 306 between the storage element 306 and the insulating material layer 330.

The shield ring 308 is formed around a substantial portion of the storage element 306. The shield ring 308 is provided to protect the storage element 306 from electrical noise from current/electric fields associated with various interconnect metal lines 326 and/or VIAs 328 in the interconnection structure. The shield ring 308 comprises a plurality of metal lines 340 and wall units 342 (that collectively form a wall) that is formed in the same architectural layer as the storage element 306. The example shield ring 308 includes a mandatory portion 309 that is formed in the same architectural layer as the storage element 306, and may include an optional portion 311 that extends to additional architectural layers above or below the storage element 306. The example shield ring 308 further includes a landing structure 313. The landing structure 313 may be disposed on a shallow trench isolation (STI) feature, silicon (Si) in an active region of a transistor, an N+ source/drain region, or a P+ source/drain region and may comprise salicide.

In this example, the storage element 306 is formed in two architectural layers—a first architectural layer above the substrate 302 and a first architectural layer in the interconnect structure. The mandatory portion 309 of the shield ring 308 is also formed in the first architectural layer above the substrate 102. The optional portion 311 of the shield ring 308 is formed in a second architectural layer in the interconnect structure.

FIG. 3B illustrates a cross-sectional view of another example semiconductor structure 350, according to some embodiments. Note that for clarity, not all features of the semiconductor structure 350 are illustrated in FIG. 3B and FIG. 3B may illustrate only a portion of the semiconductor structure formed. The example semiconductor structure 350 includes structures formed during a FEOL manufacturing process and structures formed during a BEOL manufacturing process. The example semiconductor structure 350 includes a substrate 302, a transistor device 304 formed on the substrate 302, a first storage element 306 formed on the substrate 302, a second storage element 352 formed below the substrate 302 in a backside power rail region 360 of the semiconductor structure 350, and a shield ring 354 formed around the second storage element 352. A passivation layer 344 may be formed over the semiconductor structure 350.

The example second storage element 352 comprises a bottom electrode or CBM layer 362 (e.g., similar to CBM layer 162), a top electrode or CTM layer 364 (e.g., similar to CTM layer 164), and a storage layer 366 sandwiched between the CBM layer 362 and the CTM layer 364. In various embodiments, the second storage element 352 is formed as a T-shape structure with a first portion of the CBM layer 362, storage layer 366, and the CTM layer 364 formed in the interconnect structure above an etch stop layer 338 and extending in a horizontal direction, and a second portion of the CBM layer 362, storage layer 366, and the CTM layer 364 extending in a vertical direction in a trench in a first inter metal dielectric (IMD) layer 370 and a second IMD layer 372 in the backside power rail region 360 and landing on the first source/drain region 314. The second portion of the CBM layer 362, storage layer 366, and the CTM layer 364 can be formed in a trench to improve the memory or capacitance capability of the second storage element 352. In this example, the first portion of CBM layer 362, storage layer 366, and the CTM layer 364 is oriented at an angle of approximately 90 degrees from the second portion of the CBM layer 362, storage layer 366, and the CTM layer 364 in the trench. In other embodiments, the storage element may not have a portion formed in a trench, or may not be formed as a T-shaped structure with a second portion that is oriented at an angle of approximately 90 degrees from a first portion. In various embodiments, a cap layer 368 comprising, for example, SiN, may be formed over the second storage element 352 between the second storage element 352 and the second IMD layer 372

The shield ring 354 is formed around a substantial portion of the second storage element 352. The shield ring 354 is provided to protect the second storage element 352 from electrical noise from current/electric fields associated with various interconnect metal lines and/or VIAs in the backside power rail region 360. The shield ring 354 comprises a plurality of metal lines 356 and wall units 358 (that collectively form a wall) that is formed in the same architectural layer as the second storage element 352. In some cases, the shield ring 354 may extend to additional architectural layers above or below the second storage element 352. The example shield ring 308 further includes a landing structure 357. The landing structure 357 may be disposed on a shallow trench isolation (STI) feature, silicon (Si) in an active region of a transistor, an N+ source/drain region, or a P+ source/drain region and may comprise salicide.

In this example, the second storage element 352 is formed in the two architectural layers of the backside power rail region 360. Because the second storage element 352 is coupled to the first source/drain region 314 and disposed in the first IMD layer 370 and the second IMD layer 372, the shield ring 354 is formed below the gate structure 310 and disposed in the first IMD layer 370 and the second IMD layer 372. The shield ring 354 includes a mandatory portion 353 that is formed in the same architectural layer as the storage element 352, and may include an optional portion 355 that extends to additional architectural layers above or below the storage element 352.

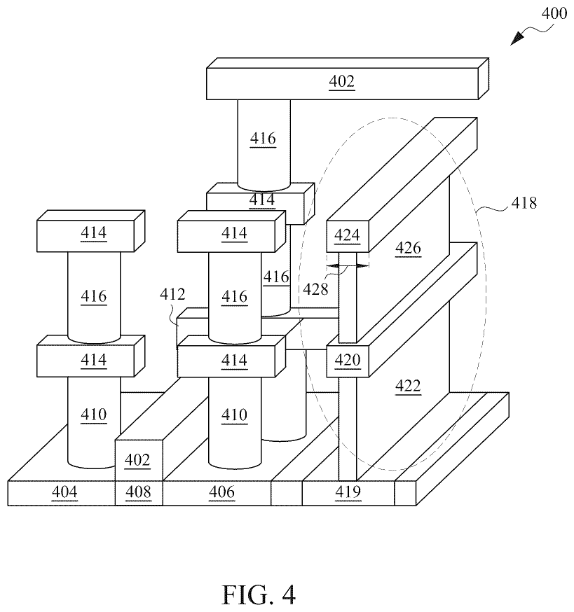

FIG. 4 is a diagram providing a three-dimensional view of a portion of an example semiconductor structure 400, according to some embodiments. Note that for clarity, not all features of the semiconductor structure 400 are illustrated in FIG. 4 and FIG. 4 may illustrate only a portion of the semiconductor structure formed. The example semiconductor structure 400 includes a transistor device (e.g., similar to transistor device 104), formed on a substrate (e.g., similar to substrate 102), comprising a gate region 402, a first source/drain region 404, a second source/drain region 406, and a channel region 408 of the substrate. The semiconductor structure 400 further includes a contact terminal 410 formed on the first source/drain region 404, a contact terminal 410 formed on the second source/drain regions 406, a storage element 412 (e.g., similar to storage element 106) formed on the second source/drain region 406, and an interconnect structure comprising metal lines 414 (e.g., similar to interconnect metal lines 126) and VIAs 416 (e.g., similar to VIAs 128) formed on or above the contact terminals 410 and storage element 412. The example semiconductor structure 400 also includes a shield ring 418 formed around the storage element 412. In some embodiments, the semiconductor structure 400 further includes, but is not limited thereto, other types of transistors, capacitors, resistors, or the like.

The shield ring 418 is provided to protect the storage element 412 from electrical noise from current/electric fields associated with various interconnect metal lines and/or VIAs in the interconnection structure. The shield ring 418 comprises metal lines 420 and metal wall units 422 that collectively form a wall that is formed in the same architectural layer as the storage element 412 and may include metal lines 424 and metal wall units 426 that collectively form a wall that extends to additional architectural layers above or below the storage element 106. The example shield ring 418 further includes a landing structure 419. The landing structure 419 may be disposed on a shallow trench isolation (STI) feature, silicon (Si) in an active region of a transistor, an N+ source/drain region, or a P+ source/drain region and may comprise salicide.

In various embodiments, the shield ring 418 has a width 428 (measured across metal lines 424) that is greater than (>) 30 nm. In various embodiments, the shield ring 418 can be arranged to protect a single storage element 412 or multiple storage elements 412. The shield ring 418 may be formed from Tungsten (W), Cobalt (Co), ruthenium (Ru), Aluminum (Al), Copper (Cu), or other suitable material. The shield ring 418 may be formed from a single film, composite film, or dopant film.

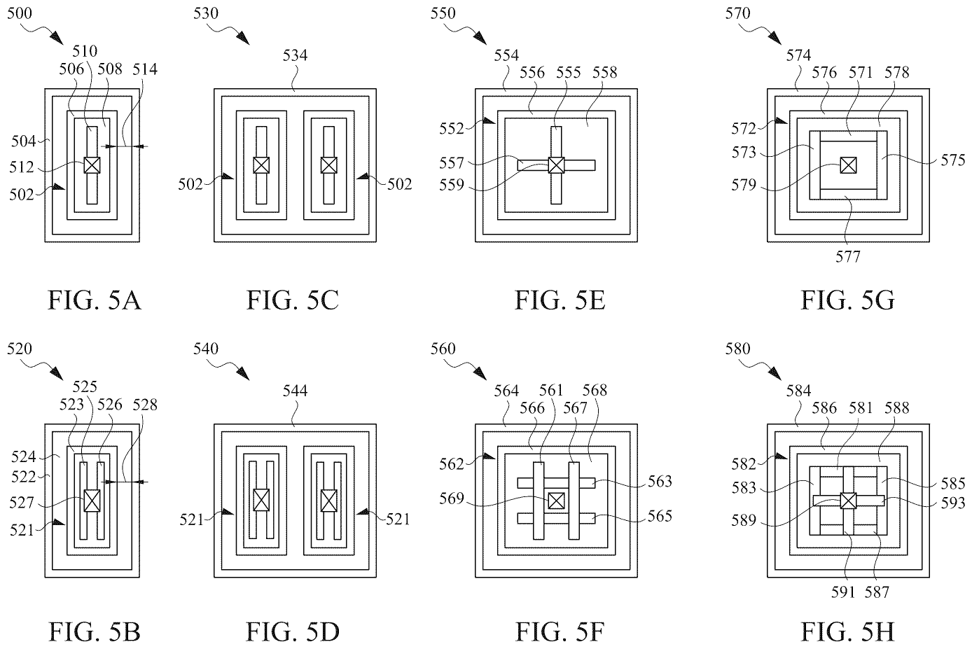

FIGS. 5A-5H are diagrams depicting top perspective views of semiconductor structures having one or more storage elements that are surrounded and protected with RF shielding by a shield ring, according to some embodiments. The shield ring can be configured to shield storage elements of different configurations and differing numberings of storage elements.

FIG. 5A is a diagram depicting a top perspective view of a semiconductor structure 500 comprising an example storage element 502 with an example shield ring 504 surrounding the storage element 502, according to some embodiments. The example storage element 502 comprises a bottom electrode 506, a top electrode 508, and a storage layer (not shown) sandwiched between the bottom electrode 506 and the top electrode 508. The storage element 502 is formed as a T-shape structure with a portion of the storage element 502 extending in a vertical direction in a trench 510. A VIA 512 is coupled to top electrode 508.

The shield ring 504 is formed around the storage element 502 to shield the storage element 502 from electrical noise from current/electric fields associated with other components of the semiconductor structure 500. In various embodiments, the shield ring 504 has a width greater than (>) 30 nm. In this example, the shield ring 504 is arranged to protect a single storage element 502. In various embodiments, the distance 514 between the shield ring 504 and the bottom electrode 506 of the storage element 502 is greater than 20 nm.

FIG. 5B is a diagram depicting a top perspective view of a semiconductor structure 520 comprising an example storage element 521 with an example shield ring 522 surrounding the storage element 521, according to some embodiments. The example storage element 521 comprises a bottom electrode 523, a top electrode 524, and a storage layer (not shown) sandwiched between the bottom electrode 523 and the top electrode 524. The storage element 521 is formed with a first portion of the storage element 521 formed in a trench 525 and a second portion of the storage element 521 formed in a trench 526. A VIA 527 is coupled to top electrode 524.

The shield ring 522 is formed around the storage element 521 to shield the storage element 521 from electrical noise from current/electric fields associated with other components of the semiconductor structure 520. In various embodiments, the shield ring 522 has a width greater than (>) 30 nm. In this example, the shield ring 522 is arranged to protect a single storage element 521. In various embodiments, the distance 528 between the shield ring 522 and the bottom electrode 523 of the storage element 521 is greater than 20 nm.

FIG. 5C is a diagram depicting a top perspective view of a semiconductor structure 530 comprising a plurality of storage elements 502 with an example shield ring 534 surrounding the storage elements 502, according to some embodiments. Each example storage element 502 comprises a bottom electrode 506, a top electrode 508, and a storage layer (not shown) sandwiched between the bottom electrode 506 and the top electrode 508. Each storage element 502 is formed as a T-shape structure with a portion of the storage elements 502 extending in a vertical direction in a trench 510. A VIA 512 is coupled to top electrode 508.

The shield ring 534 is formed around the plurality of storage elements 502 to shield the plurality of storage elements 502 from electrical noise from current/electric fields associated with other components of the semiconductor structure 530. In various embodiments, the shield ring 534 has a width greater than (>) 30 nm. In this example, the shield ring 534 is arranged to protect two storage elements 502. In other embodiments, the shield ring 534 may be arranged to protect more than two storage elements 502. In various embodiments, the shortest distance between the shield ring 504 and a bottom electrode 506 of a storage element 502 is greater than 20 nm.

FIG. 5D is a diagram depicting a top perspective view of a semiconductor structure 540 comprising a plurality of storage elements 521 with an example shield ring 544 surrounding the plurality of storage elements 521, according to some embodiments. Each example storage element 521 comprises a bottom electrode 523, a top electrode 524, and a storage layer (not shown) sandwiched between the bottom electrode 523 and the top electrode 524. Each storage element 521 is formed with a first portion of the storage element 521 formed in a trench 525 and a second portion of the storage element 521 formed in a trench 526. For each storage element 521, a VIA 527 is coupled to top electrode 524.

The shield ring 544 is formed around the plurality of storage elements 521 to shield the plurality of storage elements 521 from electrical noise from current/electric fields associated with other components of the semiconductor structure 540. In various embodiments, the shield ring 544 has a width greater than (>) 30 nm. In this example, the shield ring 544 is arranged to protect two storage elements 521. In other embodiments, the shield ring 544 may be arranged to protect more than two storage elements 521. In various embodiments, the shortest distance between the shield ring 544 and a bottom electrode 523 of a storage element 521 is greater than 20 nm.

FIG. 5E is a diagram depicting a top perspective view of a semiconductor structure 550 comprising an example storage element 552 with an example shield ring 554 surrounding the storage element 552, according to some embodiments. The example storage element 552 comprises a bottom electrode 556, a top electrode 558, and a storage layer (not shown) sandwiched between the bottom electrode 556 and the top electrode 558. The storage element 552 is formed with a first trench region 555 that intersects with a second trench region 557. A VIA 559 is coupled to the top electrode 558 in an area where the first trench region 555 intersects with the second trench region 557.

The shield ring 554 is formed around the storage element 552 to shield the storage element 552 from electrical noise from current/electric fields associated with other components of the semiconductor structure 550, according to some embodiments. In various embodiments, the shield ring 554 has a width greater than (>) 30 nm. In this example, the shield ring 554 is arranged to protect a single storage element 552. In other embodiments, the shield ring 554 may be arranged to protect a plurality of storage elements 552. In various embodiments, the shortest distance between the shield ring 554 and a bottom electrode 556 of a storage element 552 is greater than 20 nm.

FIG. 5F is a diagram depicting a top perspective view of a semiconductor structure 560 comprising an example storage element 562 with an example shield ring 564 surrounding the storage element 562, according to some embodiments. The example storage element 562 comprises a bottom electrode 566, a top electrode 568, and a storage layer (not shown) sandwiched between the bottom electrode 566 and the top electrode 568. The storage element 562 is formed with a first trench region 561 that intersects with a second trench region 563 and a third trench region 565, and a fourth trench region 567 that intersects with the second trench region 563 and the third trench region 565. A VIA 569 is coupled to the top electrode 568 in an area between the first trench region 561, the second trench region 563, the third trench region 565 and the fourth trench region 567.

The shield ring 564 is formed around the storage element 562 to shield the storage element 562 from electrical noise from current/electric fields associated with other components of the semiconductor structure 560. In various embodiments, the shield ring 564 has a width greater than (>) 30 nm. In this example, the shield ring 564 is arranged to protect a single storage element 562. In other embodiments, the shield ring 564 may be arranged to protect a plurality of storage elements 562. In various embodiments, the shortest distance between the shield ring 564 and a bottom electrode 566 of a storage element 562 is greater than 20 nm.

FIG. 5G is a diagram depicting a top perspective view of a semiconductor structure 570 comprising an example storage element 572 with an example shield ring 574 surrounding the storage element 572, according to some embodiments. The example storage element 572 comprises a bottom electrode 576, a top electrode 578, and a storage layer (not shown) sandwiched between the bottom electrode 576 and the top electrode 578. The storage element 572 is formed with a first trench region 571 that intersects at an end section with an end section of a second trench region 573 and at an end section with an end section of a third trench region 575, and a fourth trench region 577 that intersects at an end section with an end section of the second trench region 573 and at an end section with an end section of the third trench region 575. A VIA 579 is coupled to the top electrode 578 in an area between the first trench region 571, the second trench region 573, the third trench region 575 and the fourth trench region 577.

The shield ring 574 is formed around the storage element 572 to shield the storage element 572 from electrical noise from current/electric fields associated with other components of the semiconductor structure 570. In various embodiments, the shield ring 574 has a width greater than (>) 30 nm. In this example, the shield ring 574 is arranged to protect a single storage element 572. In other embodiments, the shield ring 574 may be arranged to protect a plurality of storage elements 572. In various embodiments, the shortest distance between the shield ring 574 and a bottom electrode 576 of a storage element 572 is greater than 20 nm.

FIG. 5H is a diagram depicting a top perspective view of a semiconductor structure 580 comprising an example storage element 582 with an example shield ring 584 surrounding the storage element 582, according to some embodiments. The example storage element 582 comprises a bottom electrode 586, a top electrode 588, and a storage layer (not shown) sandwiched between the bottom electrode 586 and the top electrode 588. The storage element 582 is formed with a first trench region 581 that intersects at an end section with an end section of a second trench region 583 and at an end section with an end section of a third trench region 585, a fourth trench region 587 that intersects at an end section with an end section of the second trench region 583 and at an end section with an end section of the third trench region 585, and a fifth trench region 591 that intersects a sixth trench region 593, wherein the fifth trench region 591 crosses the first trench region 581 and the fourth trench region 587, and wherein the sixth trench region 593 crosses the second trench region 583 and the third trench region 585. A VIA 589 is coupled to the top electrode 578 in an area between the first trench region 581, the second trench region 583, the third trench region 585 and the fourth trench region 587, and at the intersection of the fifth trench region 591 and the sixth trench region 593.

The shield ring 584 is formed around the storage element 582 to shield the storage element 582 from electrical noise from current/electric fields associated with other components of the semiconductor structure 580, according to some embodiments. In various embodiments, the shield ring 584 has a width greater than (>) 30 nm. In this example, the shield ring 584 is arranged to protect a single storage element 582. In other embodiments, the shield ring 584 may be arranged to protect a plurality of storage element 582. In various embodiments, the shortest distance between the shield ring 584 and a bottom electrode 586 of a storage element 582 is greater than 20 nm.

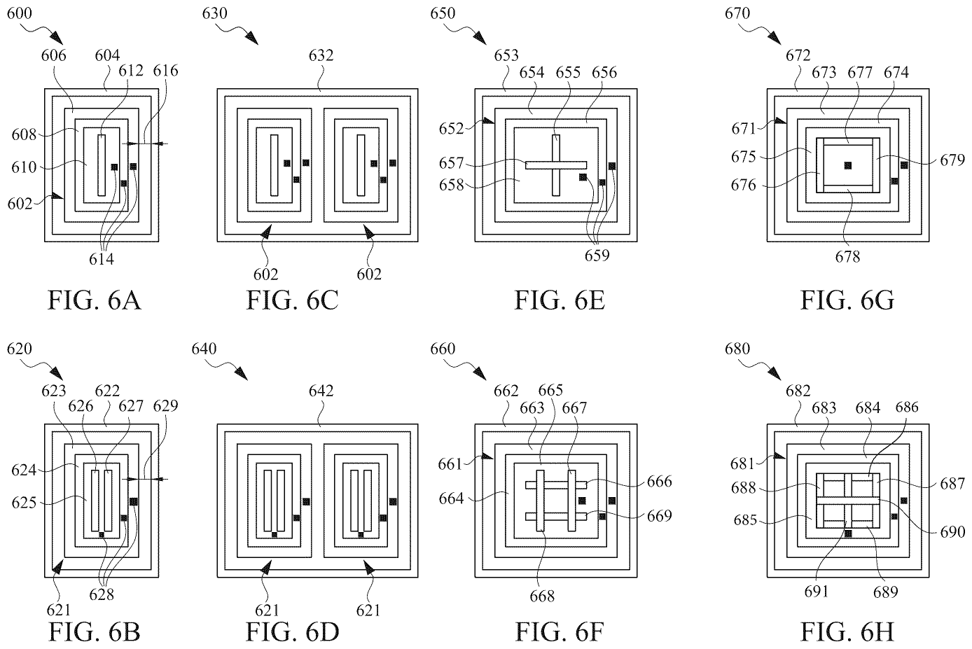

FIGS. 6A-6H are diagrams depicting top perspective views of additional semiconductor structures having one or more storage elements that are surrounded and protected with RF shielding by a shield ring, according to some embodiments. The shield ring can be configured to shield storage elements of different configurations and differing numberings of storage elements.

FIG. 6A is a diagram depicting a top perspective view of a semiconductor structure 600 comprising an example storage element 602 with an example shield ring 604 surrounding the storage element 602, according to some embodiments. The example storage element 602 comprises a first electrode 606, a second electrode 608, a third electrode 610, a first storage layer (not shown) sandwiched between the first electrode 606 and the second electrode 608, and a second storage layer (not shown) sandwiched between the second electrode 608 and the third electrode 610. The storage element 602 is formed with a portion of the storage element 602 formed in a trench 612. First, second, and third VIAs 614 are coupled to the first electrode 606, the second electrode 608, and the third electrode 610.

The shield ring 604 is formed around the storage element 602 to shield the storage element 602 from electrical noise from current/electric fields associated with other components of the semiconductor structure 600. In various embodiments, the shield ring 604 has a width greater than (>) 30 nm. In this example, the shield ring 604 is arranged to protect a single storage element 602. In various embodiments, the distance 616 between the shield ring 604 and the first electrode 606 of the storage element 602 is greater than 20 nm.

FIG. 6B is a diagram depicting a top perspective view of a semiconductor structure 620 comprising an example storage element 621 with an example shield ring 622 surrounding the storage element 621, according to some embodiments. The example storage element 621 comprises a first electrode 623, a second electrode 624, a third electrode 625, a first storage layer (not shown) sandwiched between the first electrode 623 and the second electrode 624, and a second storage layer (not shown) sandwiched between the second electrode 624 and the third electrode 625. The storage element 621 is formed with a first portion of the storage element 621 formed in a trench 626 and a second portion of the storage element 621 formed in a trench 627. First, second, and third VIAs 628 are coupled to the first electrode 623, the second electrode 624, and the third electrode 625.

The shield ring 622 is formed around the storage element 621 to shield the storage element 621 from electrical noise from current/electric fields associated with other components of the semiconductor structure 620. In various embodiments, the shield ring 622 has a width greater than (>) 30 nm. In this example, the shield ring 622 is arranged to protect a single storage element 621. In various embodiments, the distance 629 between the shield ring 622 and the first electrode 623 of the storage element 621 is greater than 20 nm.

FIG. 6C is a diagram depicting a top perspective view of a semiconductor structure 630 comprising a plurality of storage elements 602 with an example shield ring 632 surrounding the plurality of storage elements 602, according to some embodiments. Each storage element 602 comprises a first electrode 606, a second electrode 608, a third electrode 610, a first storage layer (not shown) sandwiched between the first electrode 606 and the second electrode 608, and a second storage layer (not shown) sandwiched between the second electrode 608 and the third electrode 610. Each storage element 602 is formed with a portion of the storage element 602 formed in a trench 612. For each storage element 602, first, second, and third VIAs 614 are coupled, respectively, to the first electrode 606, the second electrode 608, and the third electrode 610.

The shield ring 632 is formed around the plurality of storage elements 602 to shield the plurality of storage elements 602 from electrical noise from current/electric fields associated with other components of the semiconductor structure 630. In various embodiments, the shield ring 632 has a width greater than (>) 30 nm. In this example, the shield ring 632 is arranged to protect two storage elements 602. In other embodiments, the shield ring 632 may be arranged to protect more than two storage elements 602. In various embodiments, the shortest distance between the shield ring 632 and a first electrode 606 of a storage element 602 is greater than 20 nm.

FIG. 6D is a diagram depicting a top perspective view of a semiconductor structure 640 comprising a plurality of storage elements 621 with an example shield ring 642 surrounding the plurality of storage elements 621, according to some embodiments. Each example storage element 621 comprises a first electrode 623, a second electrode 624, a third electrode 625, a first storage layer (not shown) sandwiched between the first electrode 623 and the second electrode 624, and a second storage layer (not shown) sandwiched between the second electrode 624 and the third electrode 625. Each storage element 621 is formed with a first portion of the storage element 621 formed in a trench 626 and a second portion of the storage element 621 formed in a trench 627. For each storage element 621, first, second, and third VIAs 628 are coupled, respectively, to the first electrode 623, the second electrode 624, and the third electrode 625.

The shield ring 642 is formed around the plurality of storage elements 621 to shield the plurality of storage elements 621 from electrical noise from current/electric fields associated with other components of the semiconductor structure 640. In various embodiments, the shield ring 642 has a width greater than (>) 30 nm. In this example, the shield ring 642 is arranged to protect two storage elements 621. In other embodiments, the shield ring 642 may be arranged to protect more than two storage elements 621. In various embodiments, the shortest distance between the shield ring 642 and a first electrode 623 of a storage element 621 is greater than 20 nm.

FIG. 6E is a diagram depicting a top perspective view of a semiconductor structure 650 comprising an example storage element 652 with an example shield ring 653 surrounding the storage element 652, according to some embodiments. The example storage element 652 comprises a first electrode 654, a second electrode 656, a third electrode 658, a first storage layer (not shown) sandwiched between the first electrode 654 and the second electrode 656, and a second storage layer (not shown) sandwiched between the second electrode 656 and the third electrode 658. The storage element 652 is formed with a first trench region 655 that intersects with a second trench region 657. First, second, and third VIAs 659 are coupled, respectively, to the first electrode 654, the second electrode 656, and the third electrode 658.

The shield ring 653 is formed around the storage element 652 to shield the storage element 652 from electrical noise from current/electric fields associated with other components of the semiconductor structure 650. In various embodiments, the shield ring 653 has a width greater than (>) 30 nm. In this example, the shield ring 653 is arranged to protect a single storage element 652. In other embodiments, the shield ring 653 may be arranged to protect a plurality of storage elements 652. In various embodiments, the shortest distance between the shield ring 653 and a first electrode 654 of a storage element 652 is greater than 20 nm.

FIG. 6F is a diagram depicting a top perspective view of a semiconductor structure 660 comprising an example storage element 661 with an example shield ring 662 surrounding the storage element 661, according to some embodiments. The example storage element 661 comprises a first electrode 663, a second electrode 664, a third electrode 665, a first storage layer (not shown) sandwiched between the first electrode 663 and the second electrode 664, and a second storage layer (not shown) sandwiched between the second electrode 664 and the third electrode 665. The storage element 661 is formed with a first trench region 666 that intersects with a second trench region 667 and a third trench region 668, and a fourth trench region 669 that intersects with the second trench region 667 and the third trench region 668.

The shield ring 662 is formed around the storage element 661 to shield the storage element 661 from electrical noise from current/electric fields associated with other components of the semiconductor structure 660. In various embodiments, the shield ring 662 has a width greater than (>) 30 nm. In this example, the shield ring 662 is arranged to protect a single storage element 661. In other embodiments, the shield ring 662 may be arranged to protect a plurality of storage elements 661. In various embodiments, the shortest distance between the shield ring 662 and a first electrode 663 of a storage element 661 is greater than 20 nm.

FIG. 6G is a diagram depicting a top perspective view of a semiconductor structure 670 comprising an example storage element 671 with an example shield ring 672 surrounding the storage element 671, according to some embodiments. The example storage element 671 comprises a first electrode 673, a second electrode 674, a third electrode 675, a first storage layer (not shown) sandwiched between the first electrode 673 and the second electrode 674, and a second storage layer (not shown) sandwiched between the second electrode 674 and the third electrode 675. The storage element 671 is formed with a first trench region 676 that intersects at an end section with an end section of a second trench region 677 and at an end section with an end section of a third trench region 678, and a fourth trench region 679 that intersects at an end section with an end section of the second trench region 677 and at an end section with an end section of the third trench region 678.

The shield ring 672 is formed around the storage element 671 to shield the storage element 671 from electrical noise from current/electric fields associated with other components of the semiconductor structure 670. In various embodiments, the shield ring 672 has a width greater than (>) 30 nm. In this example, the shield ring 672 is arranged to protect a single storage element 671. In other embodiments, the shield ring 672 may be arranged to protect a plurality of storage elements 671. In various embodiments, the shortest distance between the shield ring 672 and a first electrode 673 of a storage element 671 is greater than 20 nm.

FIG. 6H is a diagram depicting a top perspective view of a semiconductor structure 680 comprising an example storage element 681 with an example shield ring 682 surrounding the storage element 681, according to some embodiments. The example storage element 681 comprises a first electrode 683, a second electrode 684, a third electrode 685, a first storage layer (not shown) sandwiched between the first electrode 683 and the second electrode 684, and a second storage layer (not shown) sandwiched between the second electrode 684 and the third electrode 685. The storage element 681 is formed with a first trench region 686 that intersects at an end section with an end section of a second trench region 687 and at an end section with an end section of a third trench region 688, a fourth trench region 689 that intersects at an end section with an end section of the second trench region 687 and at an end section with an end section of the third trench region 688, and a fifth trench region 690 that intersects a sixth trench region 691, wherein the fifth trench region 690 crosses the first trench region 686 and the fourth trench region 689, and wherein the sixth trench region 691 crosses the second trench region 687 and the third trench region 688.

The shield ring 682 is formed around the storage element 681 to shield the storage element 681 from electrical noise from current/electric fields associated with other components of the semiconductor structure 680. In various embodiments, the shield ring 682 has a width greater than (>) 30 nm. In this example, the shield ring 682 is arranged to protect a single storage element 681. In other embodiments, the shield ring 682 may be arranged to protect a plurality of storage elements 681. In various embodiments, the shortest distance between the shield ring 682 and a first electrode 683 of a storage element 681 is greater than 20 nm.

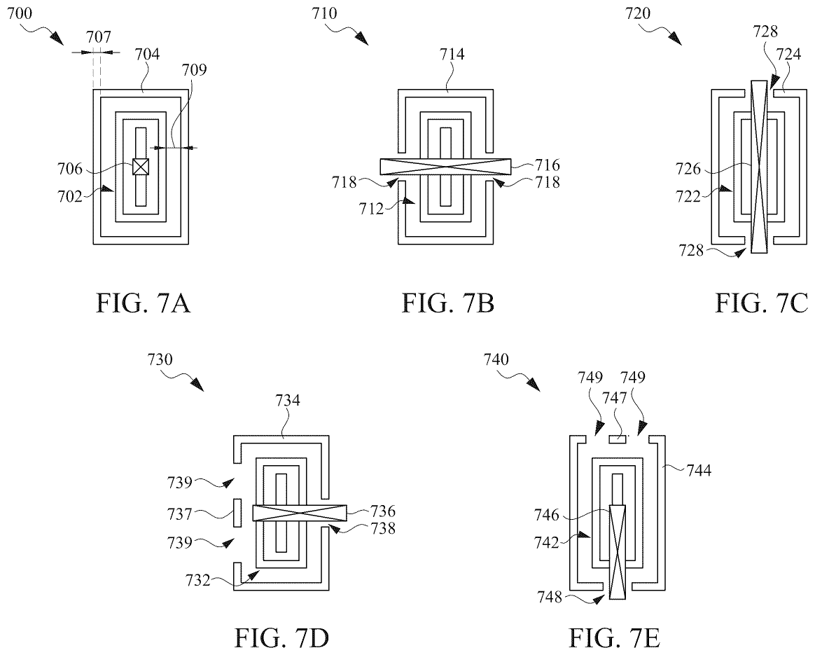

FIG. 7A is a diagram depicting a top perspective view of a semiconductor structure 700 comprising an example storage element 702 with an example shield ring 704 with a wall that surrounds the storage element 702, according to some embodiments. The semiconductor structure 700 includes metal routing 706 coupled to a top portion of the storage element 702 that extends above the storage element 702. In this example, a top view of the shield ring 704 comprises a wall that has a continuous shape around the storage element 702. In various embodiments, the continuous shape comprises a rectangular shape. In some embodiments, the continuous shape may comprise another type of shape, such as that of a hexagon, octagon, elliptical or other. In various embodiments, the wall has a thickness 707 greater than about 30 nm. In various embodiments, a closest distance 709 between the wall and a surface of the storage element 702 is greater than 20 nm.

FIG. 7B is a diagram depicting a top perspective view of a semiconductor structure 710 comprising an example storage element 712 with an example shield ring 714 with a wall that surrounds the storage element 712, according to some embodiments. The semiconductor structure 710 includes metal routing 716 coupled to a top portion of the storage element 712 that extends above the storage element 712 and laterally through the shield ring 714 on two sides in a first direction (e.g., x-direction). In this example, a top view of the shield ring 714 comprises a wall that has a non-continuous shape around the storage element 712 with a plurality of openings 718 through which the metal routing 716 extends through the shield ring 714. In various embodiments, the non-continuous shape comprises a rectangular-like shape. In some embodiments, the non-continuous shape may comprise another type of shape, such as that of a hexagon-like shape, an octagon-like shape, an elliptical-like shape, or other. In various embodiments, the wall has a thickness greater than about 30 nm. In various embodiments, a closest distance between the wall and a surface of the storage element 712 is greater than 20 nm.

FIG. 7C is a diagram depicting a top perspective view of a semiconductor structure 720 comprising an example storage element 722 with an example shield ring 724 with a wall that surrounds the storage element 722, according to some embodiments. The semiconductor structure 720 includes metal routing 726 coupled to a top portion of the storage element 722 that extends above the storage element 722 and laterally through the shield ring 724 on two sides in a first direction (e.g., y-direction). In this example, a top view of the shield ring 724 comprises a wall that has a non-continuous shape around the storage element 722 with a plurality of openings 728 through which the metal routing 726 extends through the shield ring 724. In various embodiments, the non-continuous shape comprises a rectangular-like shape. In some embodiments, the non-continuous shape may comprise another type of shape, such as that of a hexagon-like shape, an octagon-like shape, an elliptical-like shape, or other. In various embodiments, the wall has a thickness greater than about 30 nm. In various embodiments, a closest distance between the wall and a surface of the storage element 722 is greater than 20 nm.

FIG. 7D is a diagram depicting a top perspective view of a semiconductor structure 730 comprising an example storage element 732 with an example shield ring 734 with a wall that surrounds the storage element 732, according to some embodiments. The semiconductor structure 730 includes metal routing 736 coupled to a top portion of the storage element 732 that extends above the storage element 732 and laterally through the shield ring 734 on one side in a first direction (e.g., x-direction). In this example, a top view of the shield ring 734 comprises a wall that has a non-continuous shape around the storage element 732 with an opening 738 through which the metal routing 736 extends through the shield ring 734. In various embodiments, the non-continuous shape comprises a rectangular-like shape. In some embodiments, the non-continuous shape may comprise another type of shape, such as that of a hexagon-like shape, an octagon-like shape, an elliptical-like shape, or other. In various embodiments, the wall has a thickness greater than about 30 nm. In various embodiments, a closest distance between the wall and a surface of the storage element 732 is greater than 20 nm. The shield ring 734 includes a wall section 737 on a side of the shield ring 734 opposite to the opening 738 for providing shielding protection and may include openings 739 on one or more side of the wall section 737.

FIG. 7E is a diagram depicting a top perspective view of a semiconductor structure 740 comprising an example storage element 742 with an example shield ring 744 with a wall that surrounds the storage element 742, according to some embodiments. The semiconductor structure 740 includes metal routing 746 coupled to a top portion of the storage element 742 that extends above the storage element 742 and laterally through the shield ring 744 on one side in a first direction (e.g., y-direction). In this example, a top view of the shield ring 744 comprises a wall that has a non-continuous shape around the storage element 742 with an opening 748 through which the metal routing 746 extends through the shield ring 744. In various embodiments, the non-continuous shape comprises a rectangular-like shape. In some embodiments, the non-continuous shape may comprise another type of shape, such as that of a hexagon-like shape, an octagon-like shape, an elliptical-like shape, or other. In various embodiments, the wall has a thickness greater than about 30 nm. In various embodiments, a closest distance between the wall and a surface of the storage element 742 is greater than 20 nm. The shield ring 744 includes a wall section 747 on a side of the shield ring 744 opposite to the opening 748 for providing shielding protection and may include openings 749 on one or more side of the wall section 747.

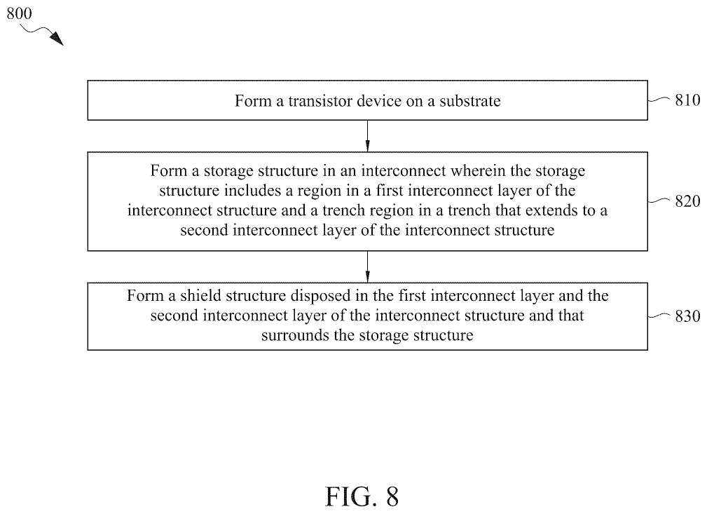

FIG. 8 is a flowchart of an example fabrication method 800, according to some embodiments. Depicted operations can be performed in a different order or not performed depending on specific applications. It should be noted that method 800 may not produce a complete semiconductor device. Accordingly, it is understood that additional processes can be provided before, during, and after method 800, and that some other processes may only be briefly described herein.

It is understood that parts of the semiconductor device may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the operations of method 800, including any descriptions given with reference to the figures are merely exemplary and are not intended to be limiting beyond what is specifically recited in the claims that follow.

At operation 810, the method 800 includes forming a transistor device on a substrate. The transistor may be a planar MOSFET device, a FinFET device, a gate-all-around (GAA) device, CFET device, and other suitable type of transistor device.

At operation 820, the method 800 includes forming a storage structure in an interconnect structure wherein the storage structure includes a region in a first interconnect layer of the interconnect structure and a trench region in a trench that extends to a second interconnect layer of the interconnect structure. In various embodiments, the storage structure includes a first electrode coupled to the transistor device, a second electrode coupled to a metal line, and a storage layer disposed between the first electrode and the second electrode.

In various embodiments, the storage structure comprises a resistive random access memory (RRAM) cell, a magnetoresistive random access memory (MRAM) cell, a phase-change random access memory (PCRAM) cell, or a ferroelectric random-access memory (FeRAM) cell. In various embodiments, the storage structure comprises a memory array comprising a plurality memory cells. In various embodiments, the storage structure comprises a capacitive device.

At operation 830, the method 800 includes forming a shield structure disposed in the first interconnect layer and the second interconnect layer of the interconnect structure and that surrounds the storage structure. In various embodiments, the shield structure extends to an additional interconnect layer above or below the first interconnect layer and the second interconnect layer. In various embodiments, the shield structure comprises a plurality of metal lines (e.g., metal lines 140) and vertically extending wall units (e.g., wall units 142) that collectively form a wall. In various embodiments, the shield structure surrounds a plurality of storage structures.

In various embodiments, the shield structure comprises a wall that surrounds the storage structure and wherein a top view of the wall comprises a continuous shape. In various embodiments, the wall has a thickness greater than 30 nm. In various embodiments, a closest distance between the wall and a surface of the storage structure is greater than 20 nm. In some embodiments, a top view of the wall comprises a non-continuous shape with an opening through which a metal line coupled to a top portion of the storage structure extends. In some embodiments, a top view of the wall comprises a non-continuous shape with a wall section on a side of the shield structure opposite an opening through which a metal line coupled to a top portion of the storage structure extends, and wherein the non-continuous shape includes openings on two sides of the wall section. In various embodiments, the storage structure and the shield structure are formed in an interconnect structure formed above the substrate. In various embodiments, the storage structure and the shield structure are formed in a backside power rail.

In some aspects, the techniques described herein relate to a semiconductor structure including: an interconnect structure including a plurality of interconnect layers formed over a substrate; a storage structure in the interconnect structure, the storage structure including a first electrode, a second electrode, and a first storage layer disposed between the first electrode and the second electrode, the storage structure including a first portion in a first interconnect layer and a second portion in a second interconnect layer; and a shield structure disposed in the first interconnect layer and the second interconnect layer of the interconnect structure, wherein the shield structure surrounds the storage structure.

In some aspects, the techniques described herein relate to a semiconductor structure, wherein the shield structure includes a wall that surrounds the storage structure and wherein a top view of the wall includes a continuous shape.

In some aspects, the techniques described herein relate to a semiconductor structure, wherein the shield structure includes a wall that surrounds the storage structure and wherein the wall has a thickness greater than 30 nm.

In some aspects, the techniques described herein relate to a semiconductor structure, wherein the shield structure includes a wall that surrounds the storage structure and wherein a closest distance between the wall and a surface of the storage structure is greater than 20 nm.

In some aspects, the techniques described herein relate to a semiconductor structure, wherein the shield structure includes a wall that surrounds the storage structure and wherein a top view of the wall includes a non-continuous shape with an opening through which a metal line coupled to a top portion of the storage structure extends.

In some aspects, the techniques described herein relate to a semiconductor structure, wherein the shield structure includes a wall that surrounds the storage structure, wherein a top view of the wall includes a non-continuous shape with a wall section on a side of the shield structure opposite an opening through which a metal line coupled to a top portion of the storage structure extends, and wherein the non-continuous shape includes openings on two sides of the wall section.

In some aspects, the techniques described herein relate to a semiconductor structure, further including: a second storage structure in a backside power rail, the second storage structure including a third electrode, a fourth electrode, and a second storage layer disposed between the third electrode and the fourth electrode, the second storage structure including a first portion in a first backside power rail layer and a second portion in a second backside power rail layer; and a second shield structure disposed in the first backside power rail layer and the second backside power rail layer of the interconnect structure and that surrounds the second storage structure.

In some aspects, the techniques described herein relate to a semiconductor structure including: a transistor device on a substrate; a storage structure in an interconnect structure and coupled to the transistor device, the storage structure including a first region in a first interconnect layer of the interconnect structure and a first trench region in a trench that extends to a second interconnect layer of the interconnect structure; and a shield structure disposed in the first interconnect layer and the second interconnect layer of the interconnect structure and that surrounds the storage structure.

In some aspects, the techniques described herein relate to a semiconductor structure, wherein the shield structure surrounds a plurality of storage structures.

In some aspects, the techniques described herein relate to a semiconductor structure, wherein the interconnect structure, the storage structure, and the shield structure are in a backside power rail.

In some aspects, the techniques described herein relate to a semiconductor structure, wherein: the first region of the storage structure extends in a horizontal direction; and the first trench region of the storage structure extends in a vertical direction.

In some aspects, the techniques described herein relate to a semiconductor structure, wherein the storage structure includes a first electrode, a second electrode, a third electrode, a first storage layer disposed between the first electrode and the second electrode, and a second storage layer disposed between the second electrode and the third electrode.

In some aspects, the techniques described herein relate to a semiconductor structure, wherein the shield structure extends to a layer in the interconnect structure above or below layers in the interconnect structure in which the storage structure is disposed.

In some aspects, the techniques described herein relate to a semiconductor structure, wherein the storage structure includes a resistive random access memory (RRAM) cell, a magnetoresistive random access memory (MRAM) cell, a phase-change random access memory (PCRAM) cell, or a ferroelectric random-access memory (FeRAM) cell.

In some aspects, the techniques described herein relate to a semiconductor structure, wherein the storage structure includes a capacitive device.

In some aspects, the techniques described herein relate to a method including: forming a transistor device on a substrate; forming a storage structure in an interconnect structure, the storage structure including a first region in a first interconnect layer of the interconnect structure and a first trench region in a trench that extends to a second interconnect layer of the interconnect structure, the storage structure including a first electrode coupled to the transistor device, a second electrode, and a storage layer disposed between the first electrode and the second electrode; and forming a shield structure disposed in the first interconnect layer and the second interconnect layer of the interconnect structure and that surrounds the storage structure.

In some aspects, the techniques described herein relate to a method, wherein forming the storage structure includes forming the storage structure with a second trench region that intersects the first trench region.

In some aspects, the techniques described herein relate to a method, wherein forming the storage structure includes forming the storage structure with a second trench region, a third trench region, and a fourth trench region, wherein the first trench region intersects with the second trench region and the third trench region, and wherein the fourth trench region intersects with the second trench region and the third trench region.

In some aspects, the techniques described herein relate to a method, wherein forming the storage structure includes forming the storage structure with a second trench region, a third trench region, and a fourth trench region, wherein the first trench region intersects at a first end section with a first end section of the second trench region and at a second end section with a first end section of a third trench region, and wherein the fourth trench region intersects at a first end section with a second end section of the second trench region and at a second end section with second end section of the third trench region.

In some aspects, the techniques described herein relate to a method, wherein forming the storage structure includes forming the storage structure with: the first electrode, the storage layer, and the second electrode extending in a horizontal direction in the first region; and the first electrode, first storage layer, and the second electrode extending in a vertical direction in the first trench region.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A semiconductor structure comprising:
an interconnect structure comprising a plurality of interconnect layers formed over a substrate;
a storage structure in the interconnect structure, the storage structure comprising a first electrode, a second electrode, and a first storage layer disposed between the first electrode and the second electrode, the storage structure comprising a first portion in a first interconnect layer and a second portion in a second interconnect layer; and
a shield structure disposed in the first interconnect layer and the second interconnect layer of the interconnect structure, wherein the shield structure surrounds the storage structure.

2. The semiconductor structure of claim 1, wherein the shield structure comprises a wall that surrounds the storage structure and wherein a top view of the wall comprises a continuous shape.

3. The semiconductor structure of claim 1, wherein the shield structure comprises a wall that surrounds the storage structure and wherein the wall has a thickness greater than 30 nm.

4. The semiconductor structure of claim 1, wherein the shield structure comprises a wall that surrounds the storage structure and wherein a closest distance between the wall and a surface of the storage structure is greater than 20 nm.

5. The semiconductor structure of claim 1, wherein the shield structure comprises a wall that surrounds the storage structure and wherein a top view of the wall comprises a non-continuous shape with an opening through which a metal line coupled to a top portion of the storage structure extends.

6. The semiconductor structure of claim 1, wherein the shield structure comprises a wall that surrounds the storage structure, wherein a top view of the wall comprises a non-continuous shape with a wall section on a side of the shield structure opposite an opening through which a metal line coupled to a top portion of the storage structure extends, and wherein the non-continuous shape includes openings on two sides of the wall section.

7. The semiconductor structure of claim 1, further comprising:
a second storage structure in a backside power rail, the second storage structure comprising a third electrode, a fourth electrode, and a second storage layer disposed between the third electrode and the fourth electrode, the second storage structure comprising a first portion in a first backside power rail layer and a second portion in a second backside power rail layer; and
a second shield structure disposed in the first backside power rail layer and the second backside power rail layer of the interconnect structure and that surrounds the second storage structure.

8. A semiconductor structure comprising:
a transistor device on a substrate;
a storage structure in an interconnect structure and coupled to the transistor device, the storage structure comprising a first region in a first interconnect layer of the interconnect structure and a first trench region in a trench that extends to a second interconnect layer of the interconnect structure; and
a shield structure disposed in the first interconnect layer and the second interconnect layer of the interconnect structure and that surrounds the storage structure.

9. The semiconductor structure of claim 8, wherein the shield structure surrounds a plurality of storage structures.

10. The semiconductor structure of claim 8, wherein the interconnect structure, the storage structure, and the shield structure are in a backside power rail.

11. The semiconductor structure of claim 8, wherein:
the first region of the storage structure extends in a horizontal direction; and
the first trench region of the storage structure extends in a vertical direction.

12. The semiconductor structure of claim 8, wherein the storage structure comprises a first electrode, a second electrode, a third electrode, a first storage layer disposed between the first electrode and the second electrode, and a second storage layer disposed between the second electrode and the third electrode.

13. The semiconductor structure of claim 8, wherein the shield structure extends to a layer in the interconnect structure above or below layers in the interconnect structure in which the storage structure is disposed.

14. The semiconductor structure of claim 8, wherein the storage structure comprises a resistive random access memory (RRAM) cell, a magnetoresistive random access memory (MRAM) cell, a phase-change random access memory (PCRAM) cell, or a ferroelectric random-access memory (FeRAM) cell.

15. The semiconductor structure of claim 8, wherein the storage structure comprises a capacitive device.

16. A method comprising:
forming a transistor device on a substrate;
forming a storage structure in an interconnect structure, the storage structure comprising a first region in a first interconnect layer of the interconnect structure and a first trench region in a trench that extends to a second interconnect layer of the interconnect structure, the storage structure comprising a first electrode coupled to the transistor device, a second electrode, and a storage layer disposed between the first electrode and the second electrode; and
forming a shield structure disposed in the first interconnect layer and the second interconnect layer of the interconnect structure and that surrounds the storage structure.

17. The method of claim 16, wherein forming the storage structure comprises forming the storage structure with a second trench region that intersects the first trench region.

18. The method of claim 16, wherein forming the storage structure comprises forming the storage structure with a second trench region, a third trench region, and a fourth trench region, wherein the first trench region intersects with the second trench region and the third trench region, and wherein the fourth trench region intersects with the second trench region and the third trench region.

19. The method of claim 16, wherein forming the storage structure comprises forming the storage structure with a second trench region, a third trench region, and a fourth trench region, wherein the first trench region intersects at a first end section with a first end section of the second trench region and at a second end section with a first end section of a third trench region, and wherein the fourth trench region intersects at a first end section with a second end section of the second trench region and at a second end section with second end section of the third trench region.

20. The method of claim 16, wherein forming the storage structure comprises forming the storage structure with:
the first electrode, the storage layer, and the second electrode extending in a horizontal direction in the first region; and
the first electrode, the storage layer, and the second electrode extending in a vertical direction in the first trench region.
